(19) United States
(12) Patent Application Publication
(10) Pub. No.: US 2005/0186722 A1
(43) Pub. Date: Aug. 25, 2005

(54) Method and structure for CMOS device with stress relaxed by ion implantation of carbon or oxygen containing ions

(76) Inventors: Kuan-Lun Cheng, Hsin-Chu (TW); Huan-Tsung Huang, Hsin-Chu (TW); Shui-Ming Cheng, Chu-bai City (TW); Yin-Pin Wang, Kaohsiung City (TW); Ka-Hing Fung, Hsin-Chu (TW)

Correspondence Address: SLATER & MATSIL, L.L.P., 17950 PRESTON ROAD, SUITE 1000, DALLAS, TX, 75252, US

(21) Appl. No.: 10/786,643

(22) Filed: Feb. 25, 2004

(51) Int. Cl. H01L 29/76; H01L 21/4763

(52) U.S. Cl. 438/199; 257/369; 257/374; 438/207

(57) ABSTRACT

Stress in a silicon nitride contact etch stop layer on a CMOS structure having NMOS and PMOS devices is selectively relieved by selective implantation of oxygen-containing or carbon-containing ions resulting in there being no tensile stress in areas of the layer above the PMOS devices and no compressive stress in areas of the layer above the NMOS devices.

### TECHNICAL FIELD

The present invention relates to a CMOS structure that includes a silicon nitride layer, and, more generally, to a method of producing such a structure and its included silicon nitride layer. More specifically, the present invention relates to a CMOS or MOSFET structure that includes p-MOS (or p-FET) and n-MOS (or n-FET) areas over which a stressed, contact etch stop layer is formed, the stress in the layer being confined to those areas in which carrier mobility and drive current are enhanced thereby and avoided or eliminated in those areas in which carrier mobility and drive current are degraded thereby.

### BACKGROUND

It is known that mechanical stress control in a channel region under a gate of a CMOS or MOSFET device can be crucial in the scaling down of device size. Mechanical stress—tensile and compressive—can increase the mobility of electrons and holes in the channel. In general, tensile stress improves electron mobility and degrades hole mobility, and compressive stress degrades electron mobility and improves hole mobility. See “Local Mechanical Stress Control (LMC): A New Technique for CMOS Performance Enhancement” by Shimizu, et al., in the 2001 IEDM Technical Digest, page 433 et seq. (“Shimizu”).

One way to produce stress in the channel is to fabricate the MOSFET on strained silicon. This may be achieved by epitaxially growing the silicon on a relaxed SiGe layer. See “Enhanced Performance in Sub-100 nm CMOSFETs Using Strained Epitaxial Silicon-Germanium” by Yee-Chia Yeo, et al., in the 2000 IEDM Technical Digest, page 753 et seq. (“Yeo”). Stressing silicon in this manner is somewhat complicated. Moreover, it has been found difficult to produce tensile-stressed silicon for n-FET areas (to enhance electron mobility) and compressively stressed silicon for p-FET areas where both are present in a single structure, ibid.

It has also been found that channel stress is produced by shallow trench isolation. See for example “A Highly Dense, High-Performance 130 nm Node CMOS Technology for Large Scale System-On-Chip Applications” by Ootsuka, et al., in the 2000 IEDM Technical Digest, page 575 et seq. (“Ootsuka”), citing “NMOS Drive Current Reduction Caused by Transistor Layout and Trench Isolation Induced Stress” by Scott, et al., in the 1999 IEDM Technical Digest, page 827 et seq. See also commonly assigned U.S. patent application Ser. No. 10/718,920, entitled “Modification of Carrier Mobility in a Semiconductor Device” by Min-Hwa Chi and Wai-Yi Lien, filed Nov. 21, 2003.

Recent studies have shown that mechanical stress is also produced in the channel when a contact etch stop layer of silicon nitride (familiarly, “SiN”) is present. See Shimizu, Ootsuka, and “Mechanical Stress Effect of Etch-Stop Nitride and its Impact on Deep Submicron Transistor Design” by Ito, et al. in the 2000 IEDM Technical Digest, page 247 et seq. (“Ito”).

Deposited silicon nitride or SiN contact etch stop layers may have inherent tensile stress or compressive stress. For example, SiN layers formed on silicon by thermal chemical vapor deposition (“TCVD”) have tensile stress, while SiN layers formed on silicon by plasma enhanced chemical vapor deposition (“PECVD”) are compressively stressed (see Ootsuka).

Ootsuka describes relaxing the stress in an SiN etch stop layer by implanting germanium ions thereinto. Implantation of germanium ions into a PECVD SiN layer relaxes the compressive stress therein. Implantation of germanium ions into a TCVD SiN layer relaxes the tensile stress therein.

### SUMMARY OF THE INVENTION

Preferred embodiments of the present invention include a CMOS structure having a stress-relaxed silicon nitride or SiN layer in which the stress is relaxed by the implantation therein of oxygen-containing or carbon-containing ions. The stress may be relaxed in selected areas of the SiN layer by preventing oxygen or carbon ion implantation in all but the selected areas, for example by appropriate masking. The stress may be tensile, as when the SiN layer is formed by TCVD, or compressive, as when the SiN layer is formed by PECVD. Typically, PMOS and NMOS devices will have been formed in and on the substrate following which these devices and the substrate will have been covered by the SiN layer. If the stress in the SiN layer is tensile, implantation of oxygen or carbon ions is prevented in areas of the layer overlying the NMOS devices. If the stress is compressive, the implantation is prevented in areas of the layer overlying the PMOS devices.

Other embodiments of the present invention contemplate methods of fabricating the above-described embodiments. Ion implantation may be prevented in selected areas of the SiN layer by masking the layer, for example by applying and developing a photoresist coating to the SiN layer.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a sectioned side view of a prior art product being modified by a method contemplated by the present invention; and

FIG. 2 is a sectioned side view of the product of FIG. 1 as modified in accordance with the present invention due to the practice of the method schematically represented in FIG. 1.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

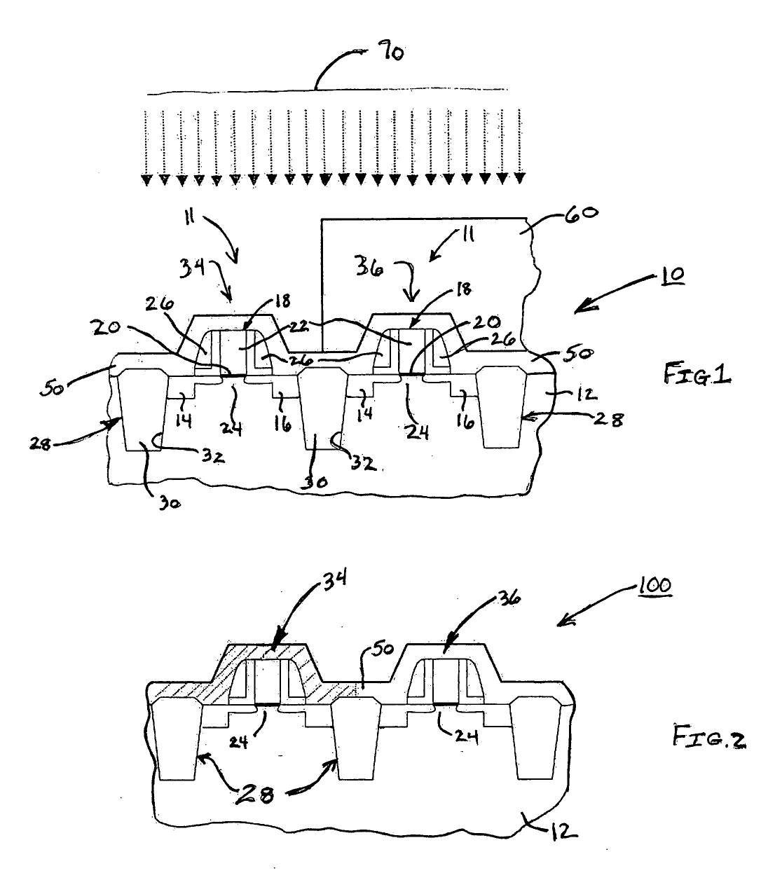

In FIG. 1 there is shown a prior art CMOS structure 10 that includes one or more transistors or other devices or elements, generally designated at 1. The structure 10, which is typically a small portion of an extensive integrated circuit or IC (not shown), includes a substrate 12. If the devices 11 are CMOS/MOSFET transistors, each may include an extended source 14 and an extended drain 16. Gate 18 resides between the source 14 and the drain 16.

As is conventional, the gate 18 includes a gate oxide or other dielectric 20, such as a high-K dielectric, that electrically insulates a gate electrode 22 from a channel 24, which lies between the source/drain 14/16 and their extended portions. Insulative spacers 26 that masked the sides of the gate 18 during formation of the source/drain 14/16 by epitaxial formation and/or ion implantation typically remain in place after such formation. Shallow trench isolation (“STI”) regions 28, which include insulative material 30 filling trenches 32 formed in the substrate 12, electrically isolate adjacent transistors or other devices or elements 11 from each other.

For purposes of the present description, the left-hand device 11 is a PMOS transistor 34 and the right-hand device 11 is an NMOS transistor 36.

A contact etch stop layer 50 is formed over the substrate 12, the sources/drains 14/16, the gates 18 and the STIs 28. At a later point in time, respective openings (not shown) are formed in the layer 50 and are filled with metal or other conductive material (not shown) that is electrically continuous with the associated source 14, drain 16 and gate electrode 22. The metal or conductive material in the openings serves as an electrical contact that enables electrical connection of other elements and devices (not shown) to the sources/drains/gate electrodes 14/16/22. Such elements and devices may reside in higher levels of the IC in which the structure 10 is included.

As noted earlier, if the substrate 12 is silicon and the layer 50 is silicon nitride that is formed by thermal chemical vapor deposition (“CVD”), there will be residual tensile stress in the layer 50, which will, in turn, produce tensile stress in the channel 24. Tensile stress in the channel 24 enhances electron mobility therein (e.g., as in the channel 24 of the NMOS transistor 36) but degrades hole mobility therein (e.g., as in the channel 24 of the PMOS transistor 34).

Thus, if the device 34 is the depicted PMOS transistor and the device 36 is the depicted NMOS transistor, a SiN layer 50 formed by thermal CVD will enhance the operation of the device 36 but will degrade the operation of the device 34. If the layer 50 is formed by plasma enhanced chemical vapor deposition (“PECVD”), the layer 50 and the channels 24 are compressively stressed, resulting in enhancement of hole mobility in the device 34 but retardation of electron mobility in the device 36.

In FIG. 1, the prior art structure 10 is subjected to a method of the present invention to produce a product of the present invention, the latter being shown in FIG. 2.

Specifically, if the SiN layer 50 has tensile stress, the area of the layer 50 overlying the NMOS device 36 is masked, as by an appropriately applied and developed photoresist coating 60 or other material that is opaque to oxygen and/or carbon ion implantation. The photoresist 60 does not mask the area of the layer 50 overlying the PMOS device 34. Thereafter, oxygen or carbon ion implantation is effected, as schematically depicted by the arrows 70. The photoresist 60 prevents the ions from reaching the area of the layer 50 superjacent to the NMOS device 36.

The oxygen or carbon ions implanted into the area of the layer 50 superjacent to the PMOS device 34 relax the tensile stress therein. This relaxation of the tensile stress results in little or no hole-mobility-degrading tensile stress in the channel 24 of the PMOS device 34. FIG. 2 depicts this condition by showing an improved structure 100 in which the unstressed area of the layer 50 over the PMOS device 34 is shaded, while the area of the layer 50 over the NMOS device 36 is unshaded, that is, it retains its tensile stress to enhance electron mobility in its channel 24.

If the SIN layer 50 is compressively stressed, as when it is formed by PECVD, the photoresist 60 is applied and developed to mask the PMOS device 34 and permit the oxygen or carbon ions to be implanted in the area of the SIN layer 50 overlying the NMOS device 36.

As an example, assume etch stop layer 50 is formed by thermal CVD to a thickness of between 100 Angstroms to 1000 Angstroms and preferably to a thickness of about 150-300 Angstroms. To relieve the tensile stress in the layer above device 34, oxygen is implanted to a concentration ranging from 2e14 to 5e16 atoms/cm³, and more preferably to about 1e15 to 6e15 atoms/cm³. Preferably, the oxygen is implanted to a depth of about 50-80% of the etch stop layer thickness.

Methods contemplated by the present invention may be used instead of, or in conjunction with, other stress-producing techniques to tailor and adjust the type and amount of stress in a channel 24 of a CMOS device 34,36. Moreover, as is clear, the present invention may be employed to selectively affect the stress of the multiple CMOS devices 34,36 contained in an integrated circuit.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A CMOS structure having a silicon nitride layer in which stress is relaxed by implantation therein of oxygen-containing or carbon-containing ions.

2. The structure of claim 1 in which stress is relaxed in a selected area by preventing ion implantation in all but the selected area.

3. The structure of claim 2 in which the preventing step is effected by masking all but the selected area.

4. The structure of claim 1 in which the stress in the layer is tensile.

5. The structure of claim 4, which further comprises a PMOS device and an NMOS device both covered by the layer, and wherein implantation of oxygen-containing or carbon-containing ions is prevented in the area of the layer overlying the NMOS device.

6. The structure of claim 1 in which the stress in the layer is compressive.

7. The structure of claim 6, which further comprises a PMOS device and an NMOS device both covered by the silicon nitride layer, and wherein implantation of the oxygen-containing or carbon-containing ions is prevented in the area of the layer overlying the PMOS device.

8. A CMOS structure having a silicon nitride contact etch stop layer overlying one or more NMOS devices and one or more PMOS devices, comprising:
first areas of the layer overlying one type of device and having oxygen-containing or carbon-containing ions implanted therein; and
second areas of the layer overlying the other type of device and not having oxygen-containing or carbon-containing ions implanted therein.

9. The structure of claim 8, wherein the layer is formed by chemical vapor deposition.

10. The structure of claim 8, wherein the layer is formed by thermal chemical vapor deposition.

11. The structure of claim 10, wherein:
the first areas overlie the PMOS devices; and
the second areas overlie the NMOS devices.

12. The structure of claim 8, wherein the layer is formed by plasma enhanced chemical vapor deposition.

13. The structure of claim 12, wherein:
the first areas overlie the NMOS devices; and
the second areas overlie the PMOS devices.

14. A method of relaxing stress in a silicon nitride layer of a CMOS structure comprising implanting oxygen-containing or carbon-containing ions into the layer.

15. The method of claim 14, further comprising preventing oxygen-containing or carbon-containing ion implantation in all but the selected area of the layer.

16. The method of claim 15, wherein the preventing step is effected by masking all but the selected area of the layer.

17. The method of claim 14, wherein the stress in the layer is tensile.

18. The method of claim 17, wherein the layer is superjacent to a PMOS device and to an NMOS device, and further comprising preventing oxygen-containing or carbon-containing ion implantation into the area of the layer overlying the NMOS device.

19. The method of claim 18, wherein the preventing step is effected by masking all but the area of the layer overlying the PMOS device.

20. The method of claim 19, wherein the masking step is effected by selectively applying and developing a photoresist coating on the layer.

21. The method of claim 14, wherein the stress in the layer is compressive.

22. The method of claim 21, wherein the layer is superjacent to a PMOS device and to an NMOS device, and further comprising preventing oxygen-containing or carbon-containing ion implantation into the area of the layer overlying the PMOS device.

23. The method of claim 22, wherein the preventing step is effected by masking all but the area of the layer overlying the NMOS device.

24. The method of claim 23, wherein the masking step is effected by selectively applying and developing a photoresist coating on the layer.

25. A method of relaxing the stress in a silicon nitride contact etch stop layer overlying one or more NMOS devices and one or more PMOS devices, comprising:
selectively implanting oxygen-containing or carbon-containing ions into areas of the layer overlying one type of device; and
simultaneously preventing implantation of the ions into areas of the layer overlying the other type of device.

26. The method of claim 25, wherein the preventing step is effected by masking the areas of the layer overlying the other type of device.

27. The method of claim 26, wherein the masking step is effected by selectively applying and developing a photoresist coating on the layer.

28. The method of claim 25, wherein the layer is formed by chemical vapor deposition.

29. The method of claim 25, wherein the layer is formed by thermal chemical vapor deposition.

30. The method of claim 29, wherein the developed photoresist masks the NMOS devices.

31. The method of claim 25, wherein the layer is formed by plasma enhanced chemical vapor deposition.

32. The method of claim 31, wherein the developed photoresist masks the PMOS devices.
